(19) United States
(12) Patent Application Publication
(10) Pub. No.: US 2008/0111194 A1
(43) Pub. Date: May 15, 2008

(54) SEMICONDUCTOR DEVICE INCLUDING A FINFET

(75) Inventor: Keizo KAWAKITA, Tokyo (JP)

Correspondence Address: YOUNG & THOMPSON, 209 Madison Street, Suite 500, ALEXANDRIA, VA, 22314, US

(73) Assignee: ELPIDA MEMORY, INC., Tokyo (JP)

(21) Appl. No.: 11/936,807

(22) Filed: Nov. 8, 2007

(30) Foreign Application Priority Data
Nov. 10, 2006 (JP) 2006-305120

(51) Int. Cl. H01L 29/78; H01L 21/336

(52) U.S. Cl. 257/365; 438/283; 257/E21.421; 257/E29.264

(57) ABSTRACT

A FinFET includes a silicon layer deposited on a silicon substrate and configuring source/drain regions and a channel region. The gate of the FinFET includes a pair of first electrode layers sandwiching therebetween the channel region in the horizontal direction with an intervention of first gate insulation films, and a second gate electrode layer overlying the channel region with an intervention of a second gate insulation film and formed in contact with top of the first electrode layers.

This application is based upon and claims the benefit of priority from Japanese patent application No. 2006-305120, the disclosure of which is incorporated herein in its entirety by reference.

### BACKGROUND OF THE INVENTION

(a) Field of the Invention

The present invention relates to a semiconductor device including a FinFET and a method for manufacturing the same.

(b) Description of the Related Art

A DRAM (dynamic random access memory) device includes an array of memory cells each including a MISFET (metal-insulator-semiconductor field-effect-transistor) formed on the surface region of a silicon substrate (semiconductor substrate), and a storage capacitor overlying the MISFET for storing therein data or electric charge via the MISFET. The electric charge stored in the capacitor is gradually reduced with the elapse of time due to the junction leakage current flowing through the channel of the MISFET. In general, a refreshment operation is periodically performed for recovering the electric charge in the DRAM device before the electric charge reduces to a specific amount in the storage capacitor.

For the DRAM device used in an electronic equipment, such as a portable equipment, it is desired to reduce the power dissipation and thus increase the operating time length without a charge thereof. In order to achieve the longer operating time, it is generally effective to improve the charge retention capability of the DRAM memory cell and to increase the time interval between the refreshment operations, which consume a considerable power.

A technique for improving the charge retention capability of a memory cell of the DRAM device is described in a literature entitled “Novel Body Tied FinFET Cell Array Transistor DRAM with Negative Word Line Operation for sub 60 nm Technology and beyond”, in 2004 Symposium on VLSI Technology Digest of Technical Papers, p. 130-131 presented by C. H. Lee et al. In the conventional planar-type FET, the channel of the FET is formed in the surface region of a silicon substrate, and the gate electrode overlies the channel region. On the other hand, in the FinFET, the channel region protrudes in the shape of a fin from the surface of the bulk silicon substrate, and the gate electrode is disposed on the top and side surfaces of the protruding channel region.

In the structure of the FinFET, since the gate electrode is provided on the top and side surfaces of the channel region with an intervention of a gate insulation film, the controllability of the electric field acting on the channel is improved, the junction leakage current is suppressed, and thus the charge retention capability of the DRAM cell is improved. In the above literature, it is recited that the silicon substrate is doped with impurities by using an ion-implantation, and the circumference of the doped region is etched away except for the channel region to obtain the structure of the FinFET.

In the process described in the above literature, the gate electrode is formed by depositing a conductive material on the entire surface to cover the fin channel and etching the conductive film to leave a film portion thereof covering the top and side surfaces of the fin channel. This etching step is performed in the condition where the aspect ratio of the etching step is considerably high, and may cause a malfunction of the patterning or a collapse of the fin channel due to the high aspect ratio. This may incur a lower product yield of the semiconductor devices.

In addition, the doping of the channel region with impurities is performed by ion-implantation through the surface of the silicon substrate, there is a tendency that the top portion of the channel region has a higher impurity concentration than the other portion, which may cause a concentration of the electric field at the top portion during operation of the FinFET.

### SUMMARY OF THE INVENTION

In view of the above problems in the conventional techniques, it is an object of the present invention to provide a semiconductor device including a FinFET in which a malfunction of the patterning and the collapse of the gate electrode can be suppressed. It is another object of the present invention to provide a method for manufacturing such a semiconductor device.

The present invention provides a semiconductor device including a MISFET (metal-insulator-semiconductor field-effect-transistor) overlying a semiconductor substrate and including source/drain regions, a channel region and a gate electrode, wherein: the source/drain regions and channel region are configured by a silicon layer deposited on the semiconductor substrate; and the gate electrode includes a first electrode layer opposing a side surface of the channel region with an intervention of a first gate insulation film, and a second electrode layer opposing a top surface of the channel region with an intervention of a second gate insulation film and formed in contact with a top surface of the first electrode layer.

The present invention also provides a method for manufacturing a semiconductor device including: forming a first electrode layer on a semiconductor substrate with an intervention of an insulator film; forming a first gate insulation film on a side surface of the first electrode layer; depositing a semiconductor layer on the semiconductor substrate and the gate insulation film, the semiconductor layer configuring source/drain regions and a channel region of a MISFET (metal-insulator-semiconductor field-effect-transistor); forming a second gate insulation film on top of the semiconductor layer; and forming a second electrode layer overlying the channel region with an intervention of the second gate insulation film and in contact with top of the first electrode layer.

The above and other objects, features and advantages of the present invention will be more apparent from the following description, referring to the accompanying drawings.

### BRIEF DESCRIPTION OF THE DRAWINGS

FIG. 1 is a top plan view of a semiconductor device including FinFETs according to an embodiment of the present invention.

FIG. 2 is a sectional view of the semiconductor device of FIG. 1, including (a) and (b) sections taken along lines A-A and B-B, respectively, in FIG. 1.

FIGS. 3A to 3O are sectional views of the semiconductor device of FIG. 1 in consecutive steps of a fabrication process is thereof, each including (a) and (b) sections corresponding to (a) and (b) sections, respectively, of FIG. 2.

### PREFERRED EMBODIMENT OF THE INVENTION

Now, an exemplary embodiment of the present invention will be described with reference to accompanying drawings.

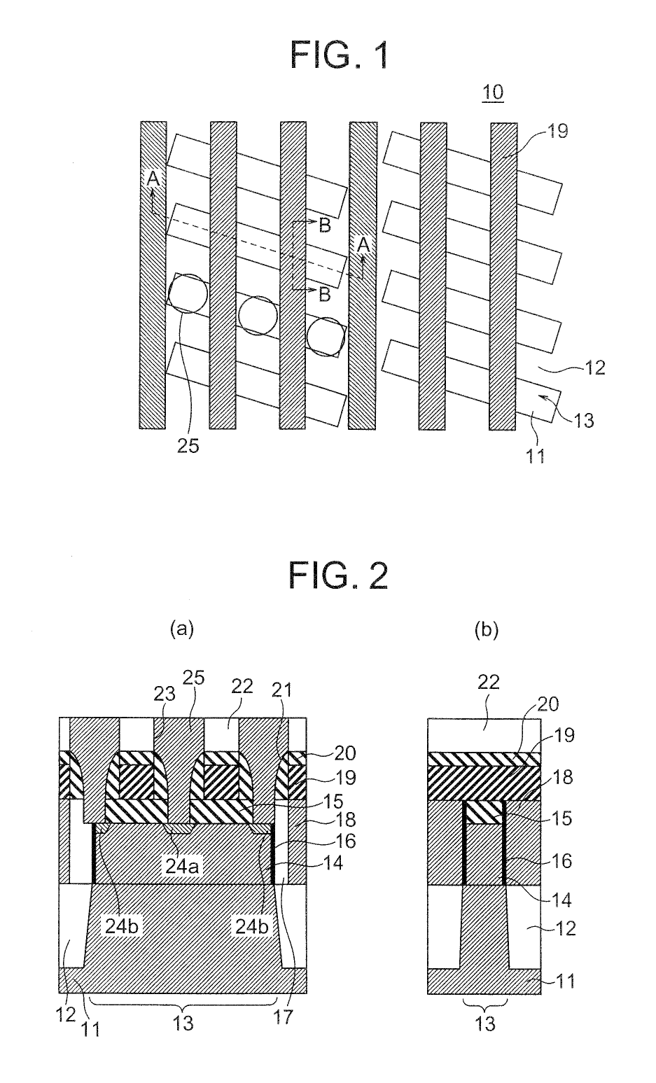

FIG. 1 is a top plan view of a semiconductor device including FinFETs according to an embodiment of the present invention. FIG. 2 is a sectional view including (a) section and (b) section taken along lines A-A and B-B, respectively, in FIG. 1. The semiconductor device, generally designated by numeral 10, is configured as a DRAM device having a 6F² structure. The semiconductor device 10 includes an isolation area 12 configured by a STI structure for isolating the area of the semiconductor substrate into a plurality of elongate, rectangular device areas 13, in each of which a pair of FinFETs are formed. The elongate device area 13 includes therein a bulk silicon substrate 11, and an epitaxial silicon layer 14 deposited on the silicon substrate 11.

The FinFET includes a first electrode layer 18 opposing both the side surfaces of the silicon layer 14 with an intervention of a side gate insulation film (first gate insulation film) 16, and a second electrode layer 19 overlying the silicon layer 14 with an intervention of a top gate insulation film (second gate insulation film) 15. The second electrode layer 19 extends in a row direction of the DRAM device across the elongate device areas 13 to configure a word line, and the bottom of the second electrode layer 19 is in contact with the top of the first electrode layer 18. The extending direction of the second electrode layer 19 crosses the elongate device areas 13 at an angle of 18 degrees deviated from the direction normal to the longitudinal direction of the elongate device area 13. A dummy word line, or dummy gate electrode overlies the STI structure 12.

The silicon layer 14 is grown on the silicon substrate 11 by using an epitaxial process. The silicon layer 14 has a cross section of an elongate rectangular shape having a vertical longer side, and extends in a horizontal direction within the elongate device area 13. The silicon layer 14 configures a fin channel region of the FinFET and is doped with impurities by an in-situ doping during the epitaxial growth. The impurities may be boron used as a p-type dopant or may be phosphor used as an n-type dopant.

The top gate insulation film 15 overlying the silicon layer 14 is made of silicon nitride, whereas the side gate insulation film 16 opposing the side surface of the silicon layer 14 is made of HTO (high temperature oxide). The top gate insulation film 15 has a thickness larger than the side gate insulation film 15, in order to prevent the electric field concentration in the top portion of the channel region configured by the silicon layer 14 and to suppress reaction between the silicon layer 14 and a metal in the second electrode layer 19 overlying the silicon layer 14.

At the longitudinal ends of the device area 13, a silicon oxide film 17 is provided outside the side gate insulation film 16, as shown in FIG. 2(a). The first electrode layer 18 extends along both the side surfaces of the silicon layer 14 with an intervention of the side gate insulation film 16, as shown in FIG. 2(b). The first electrode layer 18 is made of polysilicon doped with impurities such as boron or phosphor.

The second electrode layer 19 includes a tungsten nitride (WN) layer and an overlying tungsten (W) layer, and extends on the top gate insulating film 15 and on the top edge of the first electrode layer 18. The WN layer is formed for the purpose of suppressing reaction between the polysilicon layer configuring the first electrode layer 18 and tungsten in the W layer. A top protective film 20 made of silicon nitride is provided on top of the second electrode layer 19. The tungsten and tungsten nitride may be replaced by another refractory metal and a nitride thereof, respectively.

As shown in FIG. 2(a), a sidewall protective film 21 made of silicon nitride is formed on top of the top gate insulating film 15 and both the side surfaces of the second electrode layer 19 and top protective film 20. An interlayer dielectric film 22 made of silicon oxide is formed to cover the top gate insulating film 15, top protective film 20, and sidewall protective film 21. Contact holes 23 penetrate the interlevel dielectric film 22 and top gate insulation film 15 to expose therethrough the silicon layer 24 of the device area 13.

The silicon layer 14 exposed through the contact holes 23 is doped with impurities in the surface portion thereof, thereby configuring source region 24a and drain region 24b of the FinFET. In the present embodiment, the second electrode layer 19 functions substantially only as the word line, and thus the FinFET is substantially configured by the first electrode layer 18, source region 24a and drain region 24b. The pair of FinFETs formed in the device area 13 share a common source region 24a.

Contact plugs 25 made of polysilicon doped with impurities fill the contact holes 23. Although not illustrated, bit lines overlie the contact plugs 53 and are connected to the contact plugs 53 in contact with the source regions 24, whereas capacitors are provided on top of the contact plugs 25 connected to the drain regions 24b.

In accordance with the semiconductor device 10 of the present embodiment, the separate structure of the gate electrode including the first electrode layer 18 and second electrode layer 19 reduces the aspect ratio during patterning of the gate electrode structure, whereby a malfunction of the patterning and collapse of the patterned gate electrode structure can be suppressed. In addition, since the above separate structure allows the first electrode layer 18 to function mostly as the gate of the FinFET and the second electrode layer 19 to function mostly as a interconnection line such as a word line, the length of the first electrode layer 18 in the extending direction of the channel region may be determined independently of the corresponding width of the second electrode layer 19. This allows a reduction in the gate length of the FinFET without reducing the width of the second electrode layer 19 and thus without an increase in the propagation delay of the interconnection line configured by the second electrode layer 19.

The top gate insulation film 15 configured by the silicon nitride film suppresses the reaction between the second electrode layer including WN and W and the silicon layer 14. The larger thickness of the top gate insulation film 15 compared to the thickness of the side gate insulation film 16 alleviates the electric field concentration in the top portion of the channel region of the FinFET.

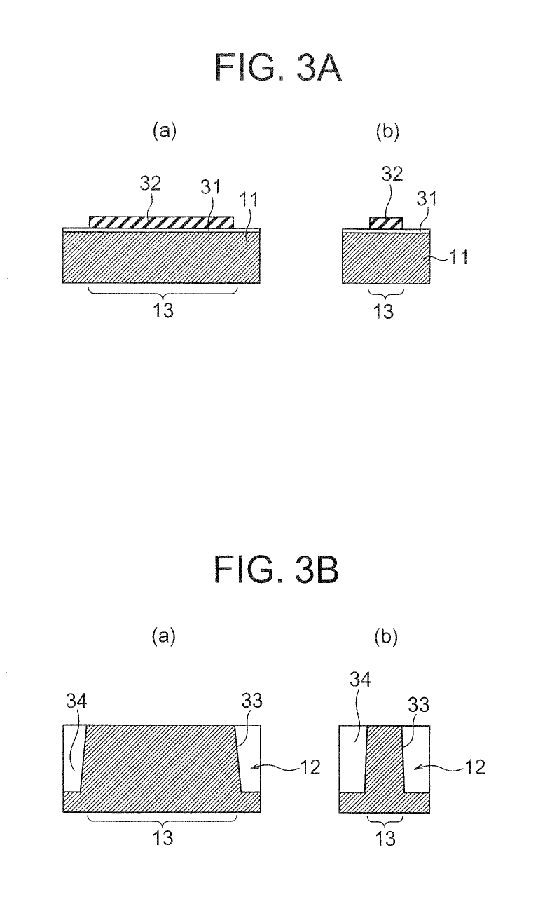

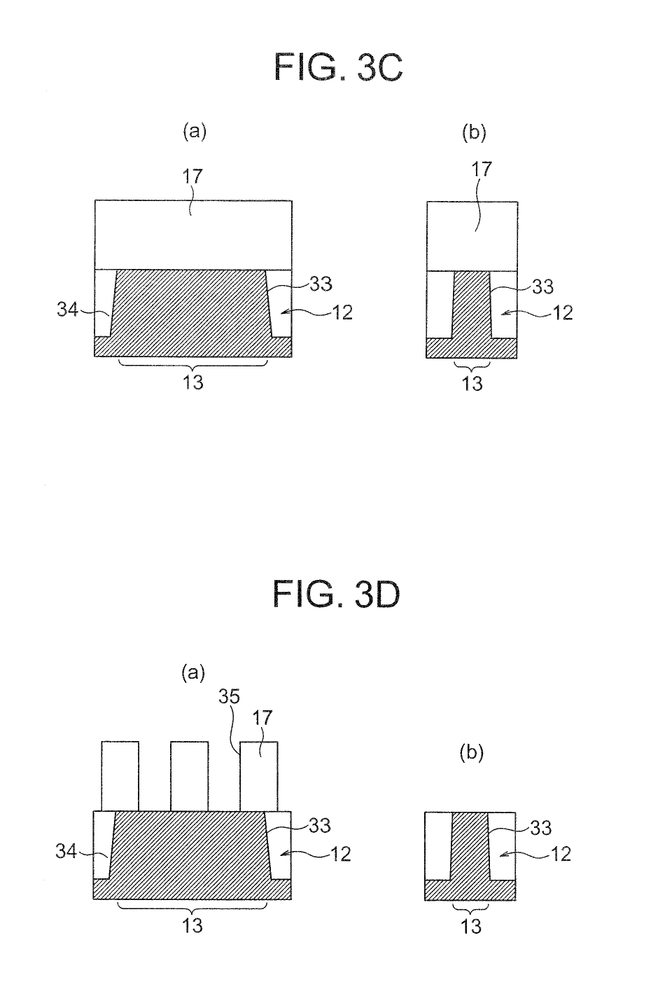

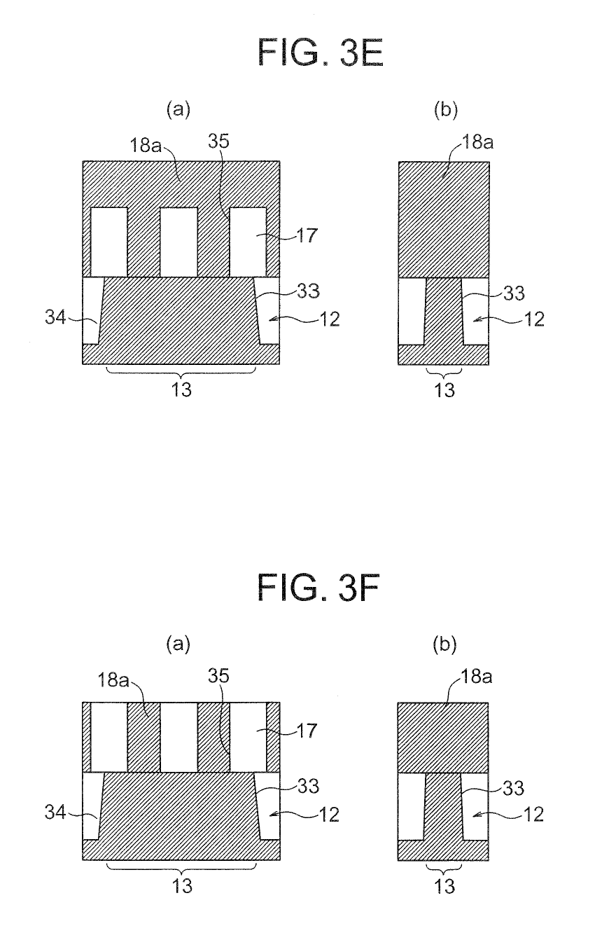

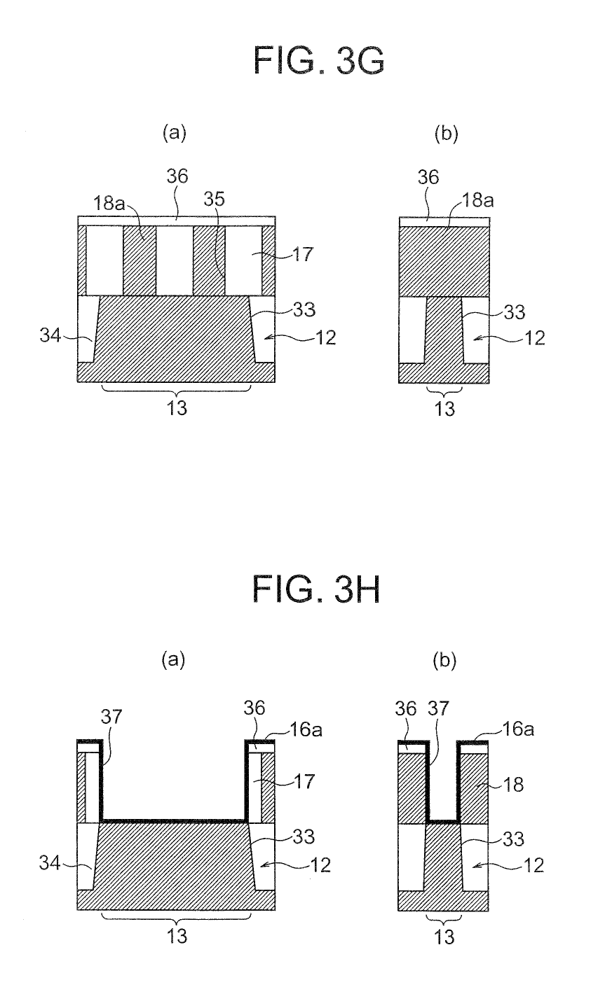

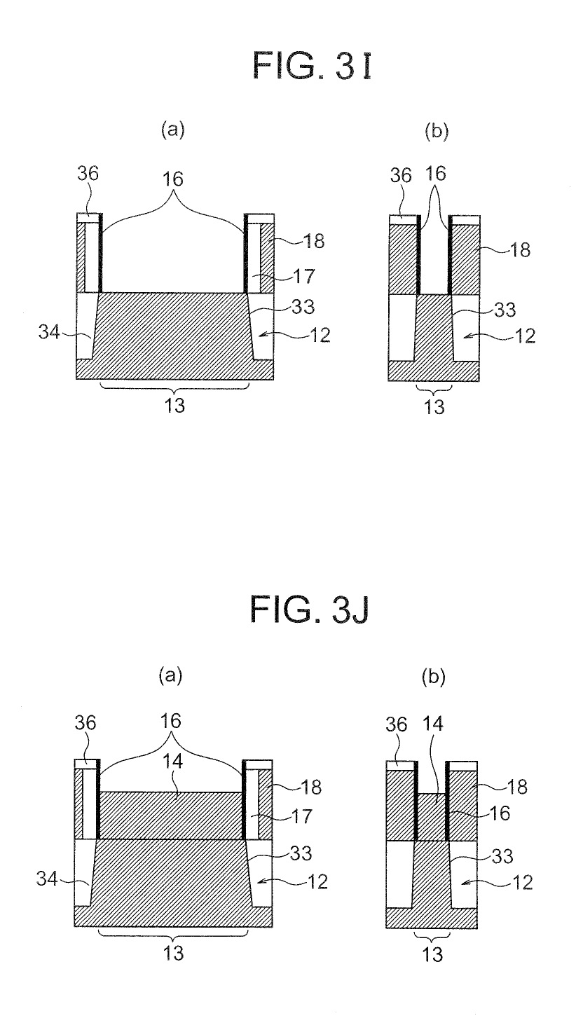

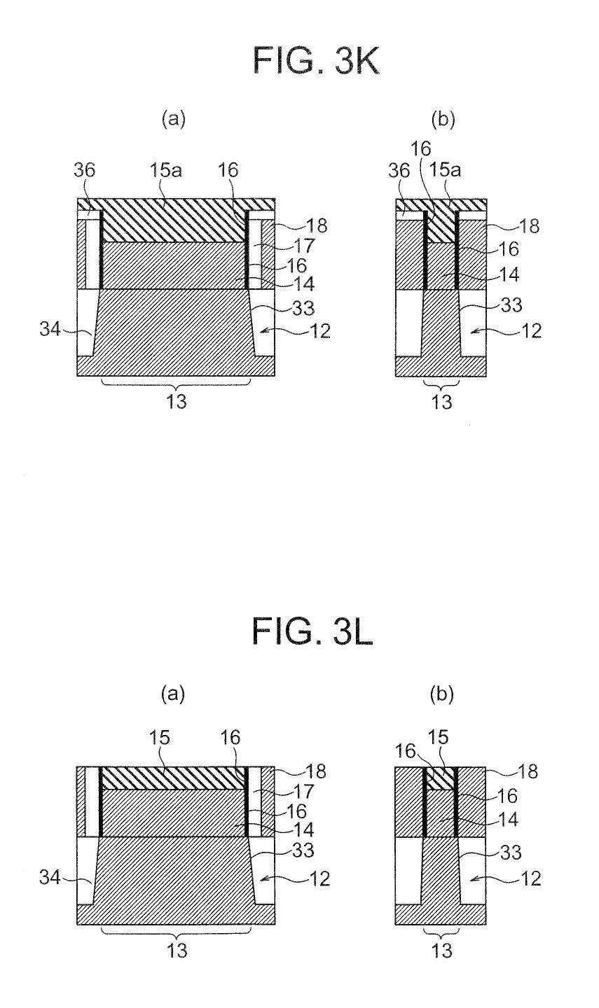

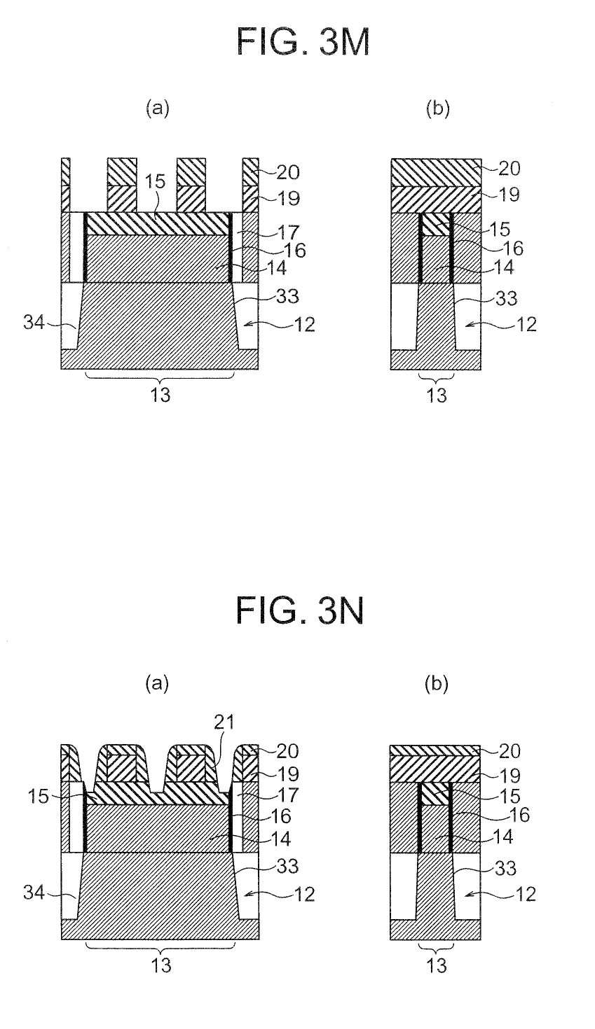

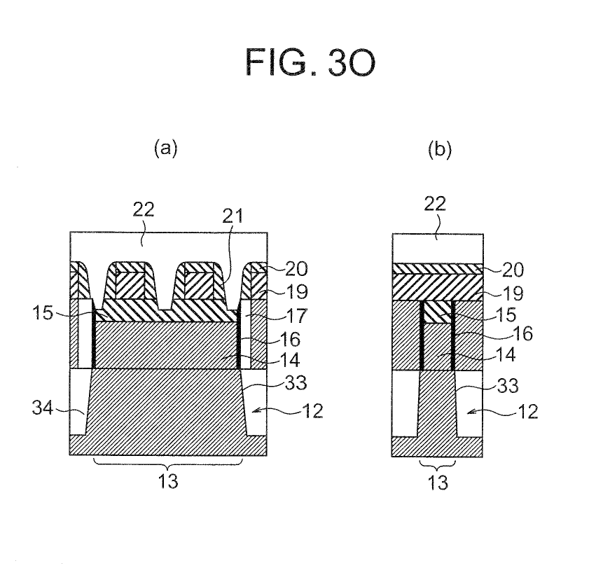

FIGS. 3A to 3O are sectional views of the semiconductor device of the present embodiment in consecutive steps of a fabrication process thereof, wherein (a) and (b) sections correspond to the (a) and (b) sections, respectively, of FIG. 2. After forming a silicon oxide film 31 on the silicon substrate 11, a silicon nitride film is deposited on the silicon oxide film 31 to a thickness of about 140 nm. A photoresist mask (not shown) having a pattern corresponding to the device areas is formed on the silicon nitride film, followed by patterning the silicon nitride film by using a dry etching technique using the photoresist mask, to obtain a hard mask 32 shown in FIG. 3A.

Thereafter, the silicon oxide film 31 is patterned by a dry etching technique using the hard mask 32 as an etching mask, and the silicon substrate 11 is also etched to a depth of about 250 nm for removal of the surface area of the silicon substrate 11 corresponding to the location of the isolation area 12, thereby forming a trench 33. Subsequently, the exposed surface of the silicon substrate 11 including the trench 33 is subjected to a thermal oxidation, to thereby form thereon an about 13-nm-thick thermal oxide film (not shown).

A silicon oxide film 34 is then formed on the entire surface by using a spin-coat technique, followed by conducting a CMP (chemical mechanical polishing) process to remove a top portion of the silicon oxide film 34 until the surface of the hard mask 32 is exposed. A wet etching process is then performed using hydrofluoric acid to etch-back the silicon oxide film 34, followed by another wet etching using phosphoric acid to remove the hard mask 32, whereby the isolation area 12 having an STI structure including the trench filled with the silicon oxide film 34 is obtained, as shown in FIG. 3B.

Thereafter, a silicon oxide film 17 is deposited on the silicon substrate 11 and isolation area 12 to a thickness of about 200 nm, as shown in FIG. 3C. A photoresist mask having an array of elongate patterns is then formed on the silicon oxide film 17. The photoresist mask is then used to selectively etch the silicon oxide film 17 to form a plurality of trenches 35 extending parallel to the location for the second electrode layer 19 of the gate electrode, to thereby obtain the structure shown in FIG. 3D.

Thereafter, a polysilicon layer 18a doped with impurities is deposited on the entire surface including the internal of trenches 35, as shown in FIG. 3E. The polysilicon layer 18a may be doped by an in-situ doping process using a p-type dopant such as boron, or an n-type dopant such as phosphor. The polysilicon layer 18a is then subjected to a CMP process for removal of the top portion thereof until top of the silicon oxide film 17 is exposed, to thereby leave the bottom portion of the polysilicon layer 18a within the trenches 35, as shown in FIG. 3F. The process including the steps shown in FIGS. 3C to 3F is referred to as a damascene process.

Subsequently, a silicon oxide film 36 is deposited to a thickness of about 50 nm on the silicon oxide film 17 and polysilicon layer 18a, as shown in FIG. 3G The silicon oxide film 36 and the underlying silicon oxide film 17 and polysilicon layer 18a are etched for removal thereof from the location of the device areas 13 by a dry etching process using a photoresist mask as an etching mask, to thereby form elongate trenches 37. The thus patterned polysilicon layer configures the first electrode layer 18 of the gate electrode.

Thereafter, a silicon oxide film (HTO film) 16a is formed on the entire surface including the internal of trenches 37 to thickness of about 7 nm by using a CVD (chemical vapor deposition) technique, at a substrate temperature of 680-700 degrees C., as shown in FIG. 3H. The HTO film 16a thus formed has a function of reducing the range of variety of impurity concentration within the silicon layer 14 to be formed later, and also has a higher film quality compared to an ordinary thermal oxide film. An etch-back process is then used to remove a portion of the HTO film 16a on the exposed surface of the silicon substrate 11 and silicon oxide film 36, to form the side gate insulation film 16 as shown in FIG. 3I.

Subsequently, silicon is epitaxially grown on the silicon substrate 11 exposed in the device areas 13, to form the silicon layer 14, as shown in FIG. 3J. The silicon layer 14 is doped in an in-situ doping process with a p-type dopant such as boron, or an n-type dopant such as phosphor. A silicon nitride film 15a is then deposited on the entire surface to a thickness of about 100 nm, as shown in FIG. 3K, followed by a CMP process until the top of the silicon oxide film 17 is exposed, to form the top gate oxide film 15, as shown in FIG. 3L.

The silicon layer 14 may be formed by epitaxially growing a non-dope silicon layer and by a subsequent ion-implantation; however, the in-situ doping process performed during the epitaxial growth in the present embodiment reduces the range of variation of impurity concentration within the resultant silicon layer 14.

Thereafter, an about 5-nm-thick WN layer and an about 50-nm-thick W layer are consecutively deposited on the entire surface, followed by depositing a silicon nitride film on the W layer. Subsequently, the silicon nitride film is patterned by a dry etching technique using a photoresist mask as an etching mask to form the top protective film 20. The top protective film 20 is then used to pattern the WN layer and W layer to obtain the second electrode layer 19 of the gate electrode, as shown in FIG. 3M.

A 20-nm-thick silicon nitride film is then formed on the entire surface to cover the second electrode layer 19 and top protective film 20, followed by etch-back thereof to form the sidewall protective film 21 on the side surface of the second electrode layer 19 and top protective film 20, as shown in FIG. 3N. The etch-back process also removes the top portion of the top protective film 20, and top gate insulation film 15 exposed from the sidewall protective film 21. A HDP (high density plasma)-CVD technique is then used to deposit a silicon oxide film configuring the interlevel dielectric film 22, which covers the top gate insulation film 15, top protective film 20 and sidewall protective film 21. The interlevel dielectric film 22 is then subjected to a CMP process for planarization of the interlevel dielectric film 22, as shown in FIG. 3O.

The interlevel dielectric film 22 is then patterned by a dry etching process using a photoresist mask as an etching mask, to form contact holes 23 exposing therethrough a potion of the silicon layer 14. This dry etching process for forming the contact holes 23 uses an etching condition allowing the silicon oxide film to be etched at an etch selectivity of 10 or above with respect to the silicon nitride film, and uses a self-alignment technique using the sidewall protective film 21 as a self-alignment etching mask. The self-alignment process for forming the contact holes 23 by using the sidewall protective film 21 prevents a short-circuit failure between the contact plugs 25 to be formed within the contact holes 23 and the second electrode layer 19 of the gate electrode.

Thereafter, ion-implantation is performed to implant impurities into the surface region of the silicon layer 14 exposed through the contact holes 23, thereby forming heavily-doped regions including the source region 24a and drain regions 24b in the silicon layer 14. A polysilicon layer doped with impurities is then deposited on the entire surface including the internal of contact holes 23, followed by a CMP process to remove a portion of the deposited polysilicon layer on the interlevel dielectric film 22, thereby obtaining the contact plugs 25 shown in FIG. 2.

The heavily-doped regions including the source region 24a and drain regions 24b may be formed by diffusing impurities introduced in the contact plugs 25 toward the silicon layer 14, after forming the contact plugs 25.

According to the method of the present embodiment, the separate structure of the gate electrode including the first electrode layer 18 disposed adjacent to the side surface of the channel region and the second electrode layer 19 disposed adjacent to the top surface of the channel region affords a lower aspect ratio during patterning for the gate electrode. This prevents a malfunction of the patterning and collapse of the structure during the patterning. In addition, since the patterning does not involve a higher aspect ratio which requires a higher-accuracy photolithographic process, the present embodiment suppresses an increase in the fabrication cost of the FinFET.

The process for depositing the silicon layer 14 configuring the channel region etc. on the bulk silicon substrate while using an in-situ doping process reduces the range of variation of impurity concentration within the channel region, whereby the electric field concentration at the top portion of the channel can be avoided.

A CVD process for forming the sidewall protection film 16 at a substrate temperature of 680 to 700 degrees C. provides a higher-quality insulation film and reduces the range of variation of the impurity concentration. This in turn reduces the range of variation of the characteristic of the FinFET, thereby improving the reliability of the semiconductor device. The HTO film 16a in the above embodiment may be replaced by a silicon nitride film, or a HfO film referred to as high-k film deposited by a CVD process.

While the invention has been particularly shown and described with reference to exemplary embodiment and modifications thereof, the invention is not limited to these embodiment and modifications. It will be understood by those of ordinary skill in the art that various changes in form and details may be made therein without departing from the spirit and scope of the present invention as defined in the claims.

What is claimed is:

1. A semiconductor device comprising a MISFET (metal-insulator-semiconductor field-effect-transistor) overlying a semiconductor substrate and including source/drain regions, a channel region and a gate electrode, wherein:
said source/drain regions and channel region are configured by a silicon layer deposited on said semiconductor substrate; and
said gate electrode includes a first electrode layer opposing a side surface of said channel region with an intervention of a first gate insulation film, and a second electrode layer opposing a top surface of said channel region with an intervention of a second gate insulation film and formed in contact with a top surface of said first electrode layer.

2. The semiconductor device according to claim 1, wherein said first and second electrode layers include different materials.

3. The semiconductor device according to claim 2, wherein said first electrode layer includes silicon and said second electrode layer includes a metal.

4. The semiconductor device according to claim 3, wherein said first electrode layer includes a pair of opposing layers sandwiching therebetween said channel region.

5. The semiconductor device according to claim 4, wherein said silicon layer is epitaxially grown on said semiconductor substrate between said opposing layers.

6. The semiconductor device according to 3, wherein said second electrode layer includes a refractory metal.

7. The semiconductor device according to claim 1, wherein said second gate insulation film includes silicon nitride.

8. A method for manufacturing a semiconductor device comprising:
forming a first electrode layer on a semiconductor substrate with an intervention of an insulator film;
forming a first gate insulation film on a side surface of said first electrode layer;
depositing a semiconductor layer on said semiconductor substrate and said gate insulation film, said semiconductor layer configuring source/drain regions and a channel region of a MISFET (metal-insulator-semiconductor field-effect-transistor);
forming a second gate insulation film on top of said semiconductor layer; and
forming a second electrode layer overlying said channel region with an intervention of said second gate insulation film and in contact with top of said first electrode layer.

9. The method according to claim 8, wherein said first electrode layer includes a pair of first electrode layers, and said semiconductor layer is sandwiched between said pair of first electrode layers.
